(19) United States
(12) Patent Application Publication
(10) Pub. No.: US 2018/0062044 A1
(43) Pub. Date: Mar. 1, 2018

(54) TRANSPARENT ELECTRODE AND MANUFACTURING METHOD THEREOF

(71) Applicants: Samsung Display Co., Ltd., Yongin-si (KR); UNIST (ULSAN NATIONAL INSTITUTE OF SCIENCE AND TECHNOLOGY), Ulsan (KR)

(72) Inventors: Gun Mo KIM, Hwaseong-si (KR); Min Woo KIM, Hwaseong-si (KR); Won Sang PARK, Yongin-si (KR); Hye Yong CHU, Hwaseong-si (KR); Jong Ho HONG, Yongin-si (KR); Si-Hoon KIM, Ulsan (KR); Ju-Young KIM, Ulsan (KR); Yun Seok NAM, Ulsan (KR); Myoung Hoon SONG, Ulsan (KR); Sang Yun LEE, Ulsan (KR)

(21) Appl. No.: 15/689,990

(22) Filed: Aug. 29, 2017

(30) Foreign Application Priority Data
Sep. 1, 2016 (KR) 10-2016-0112462

(51) Int. Cl. H01L 33/42; H01L 31/0224; H01L 51/00

(52) U.S. Cl. CPC H01L 33/42; C08F 28/00; H01L 51/0037; H01L 31/022425

(57) ABSTRACT

A transparent electrode includes: an elastic substrate; a conductive polymer layer overlapping the elastic substrate; and silver nanowires between the elastic substrate and the conductive polymer layer.

### CROSS-REFERENCE TO RELATED APPLICATION

This application claims priority from and the benefit of Korean Patent Application No. 10-2016-0112462, filed Sep. 1, 2016, which is hereby incorporated by reference for all purposes as if fully set forth herein.

### BACKGROUND

### Field

Exemplary embodiments relate to a transparent electrode and a method of manufacturing the same.

### Discussion

A transparent electrode may be applied in various applications, such as a static electricity preventing layer, a touch screen, a light emitting diode (LED), a solar cell, and the like. Indium tin oxide (ITO) has been used as a transparent electrode, and ITO has a form in which indium (In) is substituted with tin (Sn) in a crystalline structure of In₂O₃. It is also noted that ITO has relatively high electrical properties and transmittance. Fabricating components using ITO has some challenges. For instance, forming an ITO thin film typically requires a high vacuum sputtering process and a high temperature of 300° C. or more to activate the substituted tin (Sn) and to induce the crystallization. As such, there is a limit in application of ITO thin film with flexible devices.

Accordingly, conductive polymers or carbon-based materials in which a vacuum process is unnecessary and relatively low-cost printing processes are possible are attracting attention. For instance, poly(3,4-ethylenedioxythiophene) poly(styrenesulfonate) (PEDOT:PSS) in which PEDOT as one of polythiophene-based conductive polymers is modified has comparable electrical properties with amorphous ITO and relatively excellent transmission in the visible light region. It is also noted that a solution process is also possible such that PEDOT:PSS may be used as a material of a transparent electrode. In this case, however, it is difficult to realize sufficiently high enough conductivity to make the use of PEDOT:PSS practical.

The above information disclosed in this section is only for enhancement of an understanding of the background of the inventive concepts, and, therefore, it may contain information that does not form prior art already known to a person of ordinary skill in the art.

### SUMMARY

One or more exemplary embodiments provide a transparent electrode having relatively high conductivity and being stretchable.

One or more exemplary embodiments provide a method of manufacturing a transparent electrode that is stretchable and has relatively high conductivity.

Additional aspects will be set forth in the detailed description which follows, and, in part, will be apparent from the disclosure, or may be learned by practice of the inventive concepts.

According to one or more exemplary embodiments, a transparent electrode includes: an elastic substrate; a conductive polymer layer overlapping the elastic substrate; and silver nanowires between the elastic substrate and the conductive polymer layer.

According to one or more exemplary embodiments, a transparent electrode includes: a conductive polymer layer; an amphiphilic polymer material layer positioned closer to a first surface of the conductive polymer layer; and a transparent electrode including silver nanowires positioned closer to a second surface of the conductive polymer layer. The second surface opposes the first surface.

According to one or more exemplary embodiments, a method of manufacturing a transparent electrode includes: coating a solution including poly(3,4-ethylenedioxythiophene) poly(styrenesulfonate) (PEDOT:PSS) on a substrate to form a first layer; removing some PSS in the first layer to form a second layer; coating a dispersion solution including silver nanowires on the second layer to form a silver nanowire layer; coating an elastic material on the silver nanowire layer; and removing the substrate.

According to one or more exemplary embodiments, a method of manufacturing a transparent electrode includes: coating an amphiphilic polymer material layer on a transferring substrate; disposing a transparent electrode on the amphiphilic polymer material layer to form a structure, the transparent electrode including a second layer, a silver nanowire layer, and an elastic material; applying heat and pressure to the structure; and removing the elastic material.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and, together with the description, serve to explain principles of the inventive concepts.

FIGS. 1A, 1B, 1C, 1D, 1E, 1F, and 1G illustrate a transparent electrode at various stages of manufacture, according to one or more exemplary embodiments.

FIGS. 2A, 2B, and 2C illustrate a method of transferring the transparent electrode of FIG. 1G to a target, according to one or more exemplary embodiments.

FIG. 3 illustrates a transparent electrode, according to one or more exemplary embodiments.

FIG. 4 illustrates a transparent electrode, according to one or more exemplary embodiments.

FIG. 5 is a graph including results of measuring transmittance depending on wavelengths of incident illumination for a comparative transparent electrode including only a conductive polymer layer (PEDOT:PSS) and a transparent electrode according to one or more exemplary embodiments including both a conductive polymer layer (PEDOT:PSS) and a silver nanowire layer.

FIG. 6 is a graph including results of measuring a resistance change rate depending on mechanical deformation for a comparative transparent electrode including only a conductive polymer layer (PEDOT:PSS) and a transparent electrode according to one or more exemplary embodiments including both a conductive polymer layer (PEDOT:PSS) and a silver nanowire layer.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

Unless otherwise specified, the illustrated exemplary embodiments are to be understood as providing exemplary features of varying detail of various exemplary embodiments. Therefore, unless otherwise specified, the features, components, modules, layers, films, panels, regions, aspects, etc. (hereinafter collectively referred to as “elements”), of the various illustrations may be otherwise combined, separated, interchanged, and/or rearranged without departing from the disclosed exemplary embodiments.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying figures, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element is referred to as being “on,” “connected to,” or “coupled to” another element, it may be directly on, connected to, or coupled to the other element or intervening elements may be present. When, however, an element is referred to as being “directly on,” “directly connected to,” or “directly coupled to” another element, there are no intervening elements present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items. Also, for the purposes of this disclosure, the phrase “on a plane” means viewing an object portion from the top, and the phrase “on a cross-section” means viewing a cross-section in which an object portion is vertically cut from the side.

Although the terms “first,” “second,” etc. may be used herein to describe various elements, these elements should not be limited by these terms. These terms are used to distinguish one element from another element. Thus, a first element discussed below could be termed a second element without departing from the teachings of the present disclosure.

Spatially relative terms, such as “beneath,” “below,” “under,” “lower,” “above,” “upper,” “over,” and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. In this manner, regions illustrated in the drawings are schematic in nature and shapes of these regions may not illustrate the actual shapes of regions of a device, and, as such, are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

A method of manufacturing a transparent electrode and the transparent electrode will now be described with reference to the accompanying drawings.

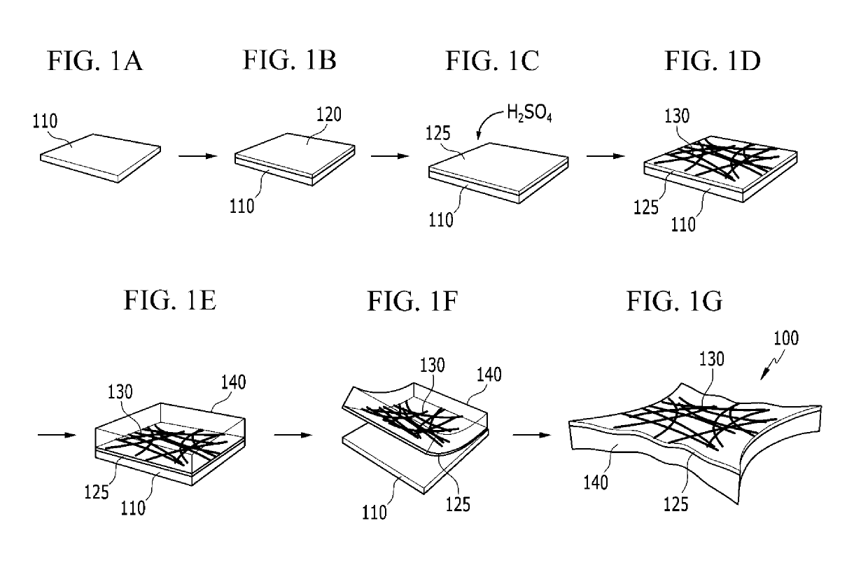

FIGS. 1A, 1B, 1C, 1D, 1E, 1F, and 1G illustrate a transparent electrode at various stages of manufacture, according to one or more exemplary embodiments.

According to one or more exemplary embodiments, a method of manufacturing a transparent electrode includes a step of coating PEDOT:PSS on a substrate to form a first layer, a step of immersing the first layer in sulfuric acid to form a second layer in which PSS is partially removed, a step of coating a dispersion solution including a silver nanowire on the second layer to form a silver nanowire layer, a step of coating an elastic material on the silver nanowire layer, and a step of removing the substrate.

Referring to FIGS. 1A and 1B, a PEDOT:PSS solution is coated on a substrate 110 to form a first layer 120. In this case, since the substrate 110 is removed in a following step, any material that is easy to remove can be used without restriction for substrate 110. For example, the substrate 110 may be glass. The first layer 120 is formed by coating the PEDOT:PSS solution such that PEDOT:PSS is included. The PEDOT:PSS solution may include Zonyl that, as a fluoric interface activator, can facilitate stretching of the finally manufactured transparent electrode. A wrinkle structure similar to a fiber is formed inside the first layer 120 by the Zonyl treatment. The wrinkle structure helps to facilitate the stretching when stretching the transparent electrode later.

With reference to FIG. 1C, the first layer 120 is immersed in sulfuric acid (H₂SO₄) to form a second layer 125 in which the PSS is partially removed. That is, the second layer 125 includes the PEDOT:PSS of which the PSS is partially removed. In this case, the PSS is not entirely removed, and only part is melted and removed in the sulfuric acid. The PEDOT:PSS is a conductive polymer material. The PEDOT, a polymerized form of 3,4-ethylenedioxythiophene (EDOT), may be oxidation-polymerized in the presence of a monomer or a polymer having a counterion capable of maintaining a charge balance and that may affect molecular weight, morphology, a doping level, and conductivity of the PEDOT depending on a polymerization method or the counterion. In this case, PEDOT:PSS is derived using polystyrene sulfonate (PSS) as a template, and is capable of being dispersed in an aqueous solution and has conductivity.

The PSS has hydrophilicity in the PEDOT:PSS. When the PSS is immersed in the sulfuric acid, rearrangement of the PEDOT is generated while the PSS is melted out in the sulfuric acid. In the rearrangement, the conductivity of the PEDOT is improved and the surface energy is changed. That is, in the case of the sulfuric acid treatment, the first layer 120 including the PEDOT:PSS is modified such that the second layer 125 including the PEDOT:PSS (of which the PSS is partially removed) is formed, and the second layer 125 has lower sheet resistance compared with the first layer 120.

As seen in FIG. 1D, a dispersion solution including silver nanowire is coated on the second layer 125 to form a silver nanowire layer 130. The silver nanowire layer 130 may include a plurality of silver nanowires formed on the second layer 125 by the dispersion solution coating.

Referring to FIG. 1E, an elastic material 140 is coated on the silver nanowire layer 130. In this case, the coated elastic material may be polydimethylsiloxane (PDMS); however, the kind of elastic material is not limited and any polymer having elasticity may be used without restriction. For instance, the elastic material 140 may include polyurethane (PU) or polyurethane acrylate (PUA). The elastic material 140 enables the stretching of the manufactured transparent electrode. That is, the elastic material 140 that is coated on the silver nanowire layer 130 is used as the stretchable elastic substrate in the finally manufactured transparent electrode.

With reference to FIG. 1F, the substrate 110 is removed from a deposition member of the elastic material 140, the silver nanowire layer 130, and the second layer 125. In this case, since attraction between the second layer 125 including the PEDOT:PSS of which the PSS is partially removed and the elastic material 140 including the PDMS is strong, the silver nanowires are fixed between the PEDOT:PSS of which the PSS is partially removed, and the PDMS.

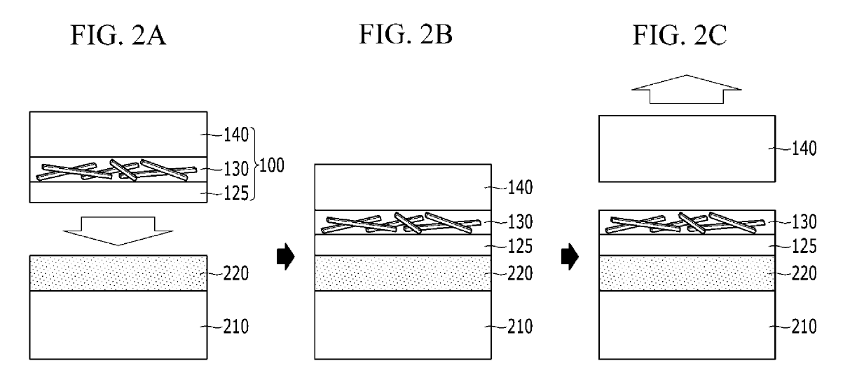

The manufactured transparent electrode 100 is shown in FIG. 1G. As seen in FIG. 1G, in the transparent electrode 100, the silver nanowire layer 130 is positioned between the elastic material 140 and the second layer 125 of the conductive polymer. Accordingly, while having the relatively high conductivity because of the silver nanowire, the stretching may be well performed since the elastic material 140 and the second layer 125 of the conductive polymer are both polymers. The transparent electrode 100 manufactured as described in association with FIGS. 1A to 1G may be used as an electrode. The transparent electrode 100 may be transferred to another object (or target), as will be described in association with FIGS. 2A to 2C.

FIGS. 2A, 2B, and 2C illustrate a method of transferring the transparent electrode of FIG. 1G to a target, according to one or more exemplary embodiments.

Referring to FIG. 2A, a transferring substrate 210 to which the transparent electrode 100 is transferred is prepared, and an amphiphilic polymer material layer 220 is formed on the transferring substrate 210.

The transferring substrate 210 may be any suitable substrate that may vary according to usage. For convenience, the transferring substrate 210 is referred to as a substrate; however, the transferring substrate 210 is not limited to a substrate, and it may be various structures applied with the transparent electrode. For instance, the transferring substrate 210 may include an organic light emitting element, a solar cell, a display device, a touch structure, etc.

The amphiphilic polymer material layer 220 may include an amphiphilic polymer. The amphiphilic polymer is a polymer together including a block having hydrophobicity and a block having hydrophilicity. The amphiphilic polymer may include a bipolar ion or a bipolar functional group therein. The amphiphilic polymer material layer 220 may include a conjugated polymer. The amphiphilic polymer having both the hydrophilicity and the hydrophobicity may easily transfer the transparent electrode 100 to the transferring substrate 210. The amphiphilic polymer material layer 220 may include PFN (poly[(9,9-bis(3′-(N,N-dimethylamino)propyl)-2, 7-fluorene)-alt-2,7-(9,9-dioctylfluorene)]) or PEI (polyethylenimine).

Referring to FIGS. 2A and 2B, the transparent electrode 100 manufactured as described in association with FIGS. 1A to 1G is positioned on the transferring substrate 210 and the amphiphilic polymer material layer 220. In this case, the transparent electrode 100 is positioned such that the second layer 125 of the transparent electrode 100 is in contact with the amphiphilic polymer material layer 220.

Next, pressure and heat are applied to combine (or adhere) the amphiphilic polymer material layer 220 and the second layer 125. In this case, since the amphiphilic polymer material layer 220 and the second layer 125 are both polymer materials, they are combined to each other by the pressure and the heat.

Referring to FIG. 2C, the pressure and the heat are removed. After the structure has cooled sufficiently, the elastic material 140 is removed. In this case, since the adherence of the amphiphilic polymer material layer 220 and the second layer 125 is stronger than the adherence of the second layer 125 and the elastic material 140, the elastic material 140 may be easily removed. As such, the second layer 125 remains on the amphiphilic polymer material layer 220. It is also noted that the silver nanowire layer 130 has higher adherence with the second layer 125 than with the elastic material 140. Accordingly, the silver nanowire layer 130 is not removed with the elastic material 140, but remains on the second layer 125.

According to one or more exemplary embodiments, the silver nanowire layer 130 is positioned at an uppermost layer, and the second layer 125 and the amphiphilic polymer material layer 220 are sequentially positioned under the silver nanowire layer 130. In other words, the second layer 125 is stacked between the silver nanowire layer 130 and the amphiphilic polymer material layer 220. The transferring method of FIG. 2 may facilitate the transferring of a stretchable electrode having conductivity. That is, the transferring method of FIG. 2 facilitates the transferring and the removal of the elastic material 140 by the adherence between the amphiphilic polymer material layer 220 and the second layer 125 since the amphiphilic polymer material layer 220 is positioned between the transferring substrate 210 and the second layer 125. Also, since the silver nanowire layer 130 and the second layer 125 are both included in the transparent electrode, the conductivity is relatively high and the second layer 125 as the polymer is increased such that transparency and the stretchability may be maintained.

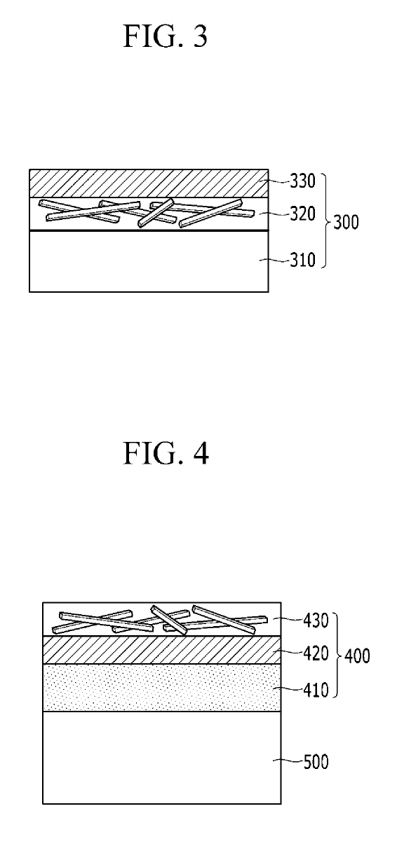

FIG. 3 illustrates a transparent electrode, according to one or more exemplary embodiments.

Referring to FIG. 3, the transparent electrode 300 has a structure in which an elastic substrate 310, a silver nanowire layer 320, and a conductive polymer layer 330 are sequentially deposited. In this manner, the silver nanowire layer 320 is stacked between the elastic substrate 310 and the conductive polymer layer 330.

The elastic substrate 310 may include the stretchable elastic polymer. The elastic substrate 310 may include the PDMS. Also, the elastic substrate 310 may include polyurethane (PU) or polyurethane acrylate (PUA). Any polymer having elasticity may be used without restriction.

The silver nanowire layer 320 is positioned on the elastic substrate 310. Although the conductive polymer layer 330 positioned on the silver nanowire layer 320 has conductivity, it has relatively low conductivity compared with a metal. As such, the conductive polymer layer 330 may not be sufficiently conductive to be used as an electrode. However, since the transparent electrode 300 according to one or more exemplary embodiments includes the silver nanowire therein, the sheet resistance of the transparent electrode 300 may be remarkably reduced and the conductivity may be improved. Also, the silver nanowire is nano-sized and is dispersed in the transparent electrode 300 such that it does not significantly affect the transparency and the stretching of the transparent electrode 300.

The conductive polymer layer 330 may provide a flat surface for the transparent electrode 300. Also, the conductive polymer layer 330 may include the PEDOT:PSS. In this case, the PEDOT:PSS is treated by the sulfuric acid and may be in a state in which the PSS is partially removed. In the removal process of the PSS, the rearrangement of the PEDOT is generated, and in the rearrangement process, the conductivity of the PEDOT is improved and the surface energy is changed. Accordingly, the acid-treated PEDOT:PSS according to one or more exemplary embodiments may have relatively low sheet resistance as compared with common (or conventional) PEDOT:PSS.

As above-described, in the transparent electrode 300 according to one or more exemplary embodiments, the silver nanowire layer 320 is positioned on the stretchable elastic substrate 310 and the conductive polymer layer 330 is positioned thereon. The elastic substrate 310 and the conductive polymer layer 330 both include the polymer material such that they may be stretchable. Also, since the conductive polymer layer 330 and the silver nanowire layer 320 are both included in the transparent electrode 300, the high sheet resistance of the conductive polymer layer 330 is compensated by the silver nanowire layer 320, thereby obtaining relatively low sheet resistance and relatively high electrical conductivity.

FIG. 4 illustrates a transparent electrode, according to one or more exemplary embodiments.

Referring to FIG. 4, the transparent electrode 400 is positioned on a supporting member 500, and includes an amphiphilic polymer material layer 410 on the supporting member 500, a conductive polymer layer 420 on the amphiphilic polymer material layer 410, and a silver nanowire layer 430 on the conductive polymer layer 420.

The supporting member 500 may have any suitable structure that is capable of positioning the transparent electrode 400. That is, all structures including an electrode, such as a light-emitting diode, a solar cell, a liquid crystal display, an organic light emitting device, and the like, may be the supporting member 500.

The amphiphilic polymer material layer 410 may include the conjugated polymer. The amphiphilic polymer material layer 410 may include PFN (poly[(9,9-bis(3′-(N, N-dimethylamino)propyl)-2,7-fluorene)-alt-2,7-(9,9-dioctylfluorene)]) or PEI (polyethylenimine). The amphiphilic polymer included in the amphiphilic polymer material layer 410 simultaneously has hydrophilicity and hydrophobicity, thereby being well combined with the conductive polymer layer 420 positioned on the amphiphilic polymer material layer 410 while being well combined with the supporting member 500.

The conductive polymer layer 420 is positioned on the amphiphilic polymer material layer 410. The conductive polymer layer 420 may include the PEDOT:PSS. In this case, the PEDOT:PSS is treated by the sulfuric acid, thereby being in a state in which the PSS is partially removed and the sheet resistance is reduced.

Next, the silver nanowire layer 430 is positioned on the conductive polymer layer 420. The silver nanowire layer 430 includes a plurality of silver nanowires. The silver nanowire remarkably reduces the sheet resistance of the transparent electrode 400 and improves the conductivity of the transparent electrode 400 without significantly affecting the transmittance of the transparent electrode 400 or the stretching characteristic.

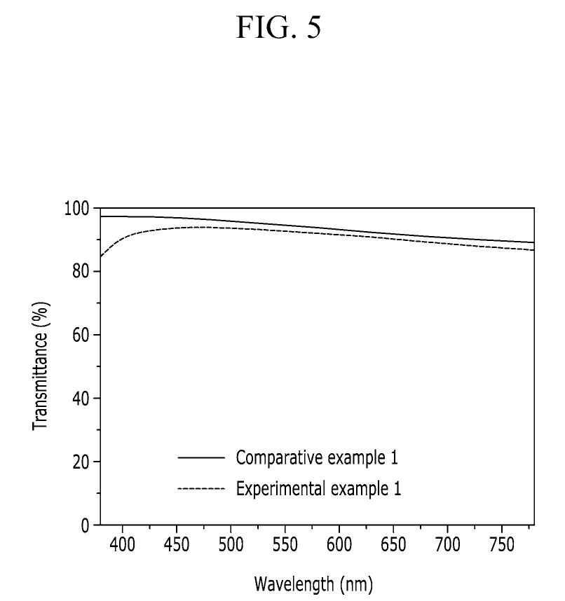

FIG. 5 is a graph including results of measuring transmittance depending on wavelengths of incident illumination for a comparative transparent electrode (Comparative Example 1) including only a conductive polymer layer (PEDOT:PSS) and a transparent electrode (Experimental Example 1) according to one or more exemplary embodiments including both a conductive polymer layer (PEDOT:PSS) and a silver nanowire (AgNW) layer. Table 1 shows the sheet resistance and the transmittance of incident illumination at 550 nm in Comparative Example 1 and Experimental Example 1.

TABLE 1

| | Rₛₕₑₑₜ | Transmittance |
|---|---|---|
| | (Ω/square) | (%) at 550 nm |
| Experimental Example 1 | 23.2 | 90.5 |
| (PEDOT:PSS + AgNAV) | | |
| Comparative Example 1 | 185.8 | 93 |
| (PEDOT:PSS) | | |

Referring to FIG. 5, the transparent electrodes of Comparative Example 1 and Experimental Example 1 show transmittance of a similar degree in the entire wavelength region. Compared with Comparative Example 1, there is a tendency for the transmittance to appear somewhat lower in Experimental Example 1, but the difference is not significant considering that a transparent electrode can have excellent performance when the actual transmittance is 90% or more. Also, as shown in Table 1, for the 550 nm wavelength, the transparent electrode of Experimental Example 1 and the transparent electrode of Comparative Example 1 both have transmittance of more than 90%.

Further, referring to Table 1, the sheet resistance of the transparent electrode of Experimental Example 1 is about 12% of the sheet resistance of the transparent electrode of Comparative Example 1. That is, the sheet resistance of Experimental Example 1 is 23.2 (Ω/square) as compared with the sheet resistance of 185.8 (Ω/square) of the transparent electrode of Comparative Example 1. As such, the transparent electrode including the silver nanowire according to Experimental Example 1 remarkably decreases the sheet resistance and significantly improves the conductivity compared with the case that the silver nanowire is not included.

According to one or more exemplary embodiments, a transparent electrode may reduce the sheet resistance to about ⅛ while maintaining the transmittance at a similar level, thereby obtaining the conductivity characteristic. Also, since the silver nanowire is dispersed with a nano-size, when bending or stretching the transparent electrode, the silver nanowire does not affect the stretching characteristic.

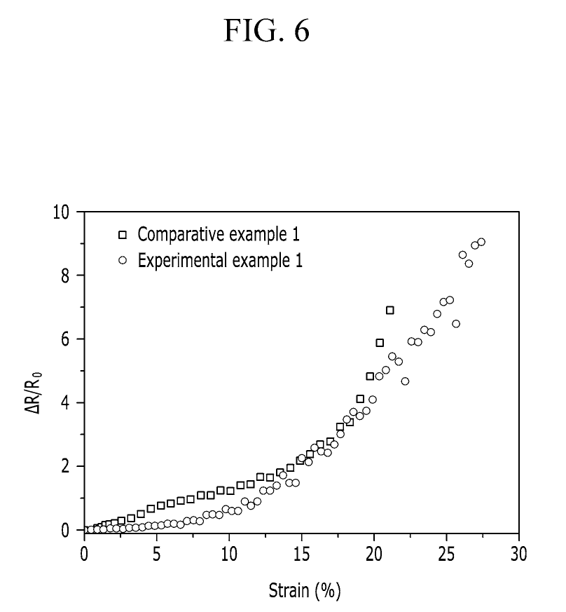

FIG. 6 is a graph including results of measuring a resistance change rate depending on mechanical deformation for a comparative transparent electrode (Comparative Example 1) including only a conductive polymer layer (PEDOT:PSS) and a transparent electrode (Experimental Example 1) according to one or more exemplary embodiments including both a conductive polymer layer (PEDOT:PSS) and a silver nanowire layer.

Referring to FIG. 6, as a strain increases in the transparent electrode of Experimental Example 1 and the transparent electrode of Comparative Example 1, the resistance change rate is increased and change degrees thereof are similar to each other. Accordingly, it may be confirmed that the transparent electrode including the silver nanowire of Experimental Example 1 does not affect the stretching characteristic or the resistance change rate depending on the stretching.

Although certain exemplary embodiments and implementations have been described herein, other embodiments and modifications will be apparent from this description. Accordingly, the inventive concepts are not limited to such embodiments, but rather to the broader scope of the presented claims and various obvious modifications and equivalent arrangements.

What is claimed is:

1. A transparent electrode comprising:
an elastic substrate;
a conductive polymer layer overlapping the elastic substrate; and
silver nanowires between the elastic substrate and the conductive polymer layer.

2. The transparent electrode of claim 1, wherein the elastic substrate comprises at least one of polydimethylsiloxane (PDMS), polyurethane (PU), and polyurethane acrylate (PUA).

3. The transparent electrode of claim 1, wherein the conductive polymer layer comprises poly(3,4-ethylenedioxythiophene) poly(styrenesulfonate) (PEDOT:PSS).

4. The transparent electrode of claim 3, wherein the PEDOT:PSS is acid-treated such that the PSS is partially removed.

5. The transparent electrode of claim 1, wherein sheet resistance of the transparent electrode is greater than 0 Ω/square and less than or equal to 30 Ω/square.

6. A transparent electrode comprising:
a conductive polymer layer;
an amphiphilic polymer material layer positioned closer to a first surface of the conductive polymer layer; and
a transparent electrode comprising silver nanowires positioned closer to a second surface of the conductive polymer layer, the second surface opposing the first surface.

7. The transparent electrode of claim 6, wherein the conductive polymer layer comprises poly(3,4-ethylenedioxythiophene) poly(styrenesulfonate) (PEDOT:PSS).

8. The transparent electrode of claim 7, wherein the PEDOT:PSS is acid-treated such that PSS is partially removed.

9. The transparent electrode of claim 6, wherein the amphiphilic polymer material layer comprises a conjugated polymer.

10. The transparent electrode of claim 6, wherein the amphiphilic polymer material layer comprises poly[(9,9-bis(3′-(N,N-dimethylamino)propyl)-2,7-fluorene)-alt-2, 7-(9,9-dioctylfluorene)](PFN) or polyethylenimine (PEI).

11. The transparent electrode of claim 6, wherein sheet resistance of the transparent electrode is greater than 0 Ω/square and less than or equal to 30 Ω/square.

12. A method of manufacturing a transparent electrode, the method comprising:
coating a solution comprising poly(3,4-ethylenedioxythiophene) poly(styrenesulfonate) (PEDOT:PSS) on a substrate to form a first layer;
removing some PSS in the first layer to form a second layer;
coating a dispersion solution comprising silver nanowires on the second layer to form a silver nanowire layer;
coating an elastic material on the silver nanowire layer; and
removing the substrate.

13. The method of claim 12, wherein the solution further comprises Zonyl.

14. The method of claim 12, wherein the elastic material comprises at least one of polydimethylsiloxane (PDMS), polyurethane (PU), and polyurethane acrylate (PUA).

15. A method of manufacturing a transparent electrode, the method comprising:
coating an amphiphilic polymer material layer on a transferring substrate;
disposing a transparent electrode on the amphiphilic polymer material layer to form a structure, the transparent electrode comprising a second layer, a silver nanowire layer, and an elastic material;
applying heat and pressure to the structure; and
removing the elastic material.

16. The method of claim 15, wherein the amphiphilic polymer material layer comprises a conjugated polymer.

17. The method of claim 15, wherein the material layer of the amphiphilic polymer comprises poly[(9,9-bis(3′-(N,N-dimethylamino)propyl)-2,7-fluorene)-alt-2, 7-(9,9-dioctylfluorene)](PFN) or polyethylenimine (PEI).

18. The method of claim 12, wherein sheet resistance of the transparent electrode is greater than 0 Ω/square and less than or equal to 30 Ω/square.

19. The method of claim 12, wherein removing some PSS in the first layer to form a second layer comprises immersing the first layer in sulfuric acid.

20. The method of claim 15, wherein the second layer, the silver nanowire layer, and the elastic material are sequentially stacked on the amphiphilic polymer material layer.
